(19) United States
(12) Patent Application Publication
(10) Pub. No.: US 2025/0141186 A1
(43) Pub. Date: May 1, 2025

(54) SEMICONDUCTOR LASER ELEMENT

(71) Applicant: Mitsubishi Electric Corporation, Tokyo (JP)

(72) Inventors: Kenichi ABE, Chiyoda-ku, Tokyo (JP); Koichi AKIYAMA, Chiyoda-ku, Tokyo (JP); Satoshi NISHIKAWA, Chiyoda-ku, Tokyo (JP)

(73) Assignee: Mitsubishi Electric Corporation, Tokyo (JP)

(21) Appl. No.: 18/689,471

(22) PCT Filed: Sep. 14, 2022
(86) PCT No.: PCT/JP2022/034416

§ 371 Date: Mar. 6, 2024

(30) Foreign Application Priority Data
Sep. 16, 2021 (WO) PCT/JP2021/034150

(51) Int. Cl. H01S 5/10; H01S 5/12

(52) U.S. Cl. CPC H01S 5/1014; H01S 5/12

(57) ABSTRACT

A semiconductor laser element includes: a semiconductor laser portion; a transition portion that is adjacent to the semiconductor laser portion in a first direction and a spot size converter that is adjacent to the transition portion in the first direction. Each of the semiconductor laser portion, the transition portion and the spot size converter includes: a semiconductor substrate having a first surface; and a first clad layer, an active layer and a second clad layer stacked on the first surface in this order from the first surface side in a third direction orthogonal to the first surface. Each of the transition portion and the spot size converter further includes a waveguide layer that is in contact with a part of an upper surface of the second clad layer and has a refractive index higher than refractive indexes of the active layer and the second clad layer.

### TECHNICAL FIELD

The present disclosure relates to a semiconductor laser element, and particularly to a semiconductor laser element having a spot size converter (hereinafter, referred to as “SSC”) integrated therein.

### BACKGROUND ART

Recently, in optical communication, an amount of communication has been continuously increasing and an increase in communication capacity has been required. Therefore, it has been required to provide a high-frequency-operating and high-output element inexpensively as a semiconductor laser element used in a light source for optical communication.

In a semiconductor laser element described in Japanese Patent Laying-Open No. 2021-27310 (PTL 1), in order to provide a high-frequency-operating and high-output element, a current injection portion is narrowed and light confinement to a narrow region is performed by a core layer structure having a high-refractive-index layer inserted therein, to thereby improve a frequency response.

A semiconductor laser element described in Japanese Patent Laying-Open No. 2016-96310 (PTL 2) includes a semiconductor laser portion including a quantum well layer, and an SSC including a waveguide layer that is monolithically butt-connected to one end (emission end) of the quantum well layer of the semiconductor laser portion. According to such a semiconductor laser element, an increase in spread angle of a laser beam emitted from the semiconductor laser portion is suppressed and higher coupling efficiency is achieved, as compared with the semiconductor laser element described in PTL 1.

### CITATION LIST

### Patent Literature

PTL 1: Japanese Patent Laying-Open No. 2021-27310

PTL 2: Japanese Patent Laying-Open No. 2016-96310

### SUMMARY OF INVENTION

### Technical Problem

However, in a method for manufacturing the semiconductor laser element described in PTL 2, it is necessary to sequentially perform the step of forming the quantum well layer on an entire surface of a semiconductor substrate, the step of partially removing the quantum well layer in a region where the SSC is to be formed, and the step of forming the waveguide layer in the region where the quantum well layer has been removed. Such a manufacturing method results in the relatively large number of steps and the relatively high manufacturing cost.

A main object of the present disclosure is to provide a semiconductor laser element that is lower in manufacturing cost than a conventional semiconductor laser element including an SSC, although the semiconductor laser element includes an SSC.

### Solution to Problem

A semiconductor laser element according to the present disclosure includes: a semiconductor laser portion; a transition portion that is adjacent to the semiconductor laser portion in a first direction and receives light emitted from the semiconductor laser portion; and a spot size converter that is adjacent to the transition portion in the first direction and receives the light emitted from the transition portion. Each of the semiconductor laser portion, the transition portion and the spot size converter includes: a semiconductor substrate having a first surface extending along the first direction and a second direction orthogonal to the first direction; and a first clad layer, an active layer and a second clad layer stacked on the first surface in this order from the first surface side in a third direction orthogonal to the first surface. In the semiconductor laser portion, the second clad layer is in contact with the active layer. A refractive index of the second clad layer is lower than a refractive index of the active layer. Each of the transition portion and the spot size converter further includes a waveguide layer that is in contact with a part of an upper surface of the second clad layer and has a refractive index higher than the refractive indexes of the active layer and the second clad layer.

### Advantageous Effects of Invention

According to the present disclosure, there can be provided a semiconductor laser element that is lower in manufacturing cost than a conventional semiconductor laser element including an SSC, although the semiconductor laser element includes an SSC.

### BRIEF DESCRIPTION OF DRAWINGS

FIG. 1 is a cross-sectional view of a semiconductor laser element according to a first embodiment.

FIG. 2 is a cross-sectional view when viewed from line II-II in FIG. 1.

FIG. 3 is a cross-sectional view when viewed from line III-III in FIG. 1.

FIG. 4 is a cross-sectional view when viewed from line IV-IV in FIGS. 2 and 3.

FIG. 5 is a cross-sectional view when viewed from line V-V in FIGS. 2 and 3.

FIG. 6 is a cross-sectional view when viewed from line VI-VI in FIGS. 2 and 3.

FIG. 7 is a cross-sectional view when viewed from line VII-VII in FIGS. 2 and 3.

FIG. 8 is a flowchart for illustrating a first step of a method for manufacturing the semiconductor laser element according to the first embodiment.

FIG. 9 is a cross-sectional view of a semiconductor laser element according to a second embodiment.

FIG. 10 is a cross-sectional view when viewed from line X-X in FIG. 9.

FIG. 11 is a cross-sectional view when viewed from line XI-XI in FIG. 9.

FIG. 12 is a flowchart for illustrating a first step of a method for manufacturing the semiconductor laser element according to the second embodiment.

FIG. 13 is a cross-sectional view of a semiconductor laser element according to a third embodiment.

FIG. 14 is a cross-sectional view when viewed from line XIV-XIV in FIG. 13.

FIG. 15 is a cross-sectional view when viewed from line XV-XV in FIG. 13.

FIG. 16 is a cross-sectional view when viewed from line XVI-XVI in FIG. 13.

FIG. 17 is a flowchart for illustrating a first step of a method for manufacturing the semiconductor laser element according to the third embodiment.

### DESCRIPTION OF EMBODIMENTS

Hereinafter, embodiments of the present disclosure will be described with reference to the drawings. FIGS. 1 to 6, 8 to 11 and 13 to 16 show a Cartesian coordinate system having an X direction (second direction), a Y direction (first direction) and a Z direction (third direction) that are orthogonal to each other.

When geometric terms and terms representing positional, directional and magnitude relations are used in the present embodiment, for example, when terms such as “orthogonal”, “along”, “equal”, and “constant” are used, these terms permit fluctuations based on manufacturing errors.

### First Embodiment

### Configuration of Semiconductor Laser Element 100

As shown in FIG. 1, a semiconductor laser element 100 according to a first embodiment includes a semiconductor laser portion 1, a transition portion 2 and a spot size converter (SSC) 3. Semiconductor laser element 100 is an element having semiconductor laser portion 1, transition portion 2 and SSC 3 monolithically integrated therein.

Semiconductor laser portion 1 includes a multiple quantum well layer and is provided to emit light. Transition portion 2 is provided to receive the light emitted from semiconductor laser portion 1. Transition portion 2 is adjacent to semiconductor laser portion 1 in the Y direction. In other words, transition portion 2 is directly connected to semiconductor laser portion 1 in the Y direction. SSC 3 is provided to receive the light emitted from transition portion 2. SSC 3 is adjacent to transition portion 2 in the Y direction. In other words, SSC 3 is directly connected to transition portion 2 in the Y direction.

### Configuration of Semiconductor Laser Portion 1

As shown in FIGS. 1 to 4, semiconductor laser portion 1 includes a semiconductor substrate 5, a first clad layer 6, a diffraction grating layer 7, an active layer 11, a second clad layer 12, a fourth clad layer 15, and an insulating layer 16, and a first electrode 17, an electrode pad 18 and a second electrode 19.

Semiconductor substrate 5 has a first surface 5A and a second surface 5B located opposite to first surface 5A. Each of first surface 5A and second surface 5B extends along the X direction and the Y direction. Semiconductor substrate 5 is made of, for example, p-type InP.

First clad layer 6, active layer 11 and second clad layer 12 are provided on first surface 5A and are stacked in this order from the first surface 5A side in the Z direction. First clad layer 6, active layer 11 and second clad layer 12 form p-i-n junction. First clad layer 6 and second clad layer 12 are provided to sandwich active layer 11 in the Z direction. Each of first clad layer 6 and second clad layer 12 is in contact with active layer 11. Active layer 11 includes a multiple quantum well layer. In other words, active layer 11 has a multiple quantum well structure formed by alternately stacking a plurality of quantum well layers and a plurality of barrier layers in the Z direction.

A material constituting the multiple quantum well layer and the barrier layers of active layer 11 may be arbitrarily selected depending on an emission wavelength. For example, when the emission wavelength of active layer 11 is 1.31 μm, each of the multiple quantum well layer and the barrier layers of active layer 11 is made of, for example, InGaAsP.

A composition ratio of InGaAsP, which is a quaternary mixed crystal, is generally expressed as In₁₋ₓGaₓAs_{y}P_{1-y} and has two degrees of freedom of x and y. It is known that a refractive index of InGaAsP varies by adjusting the values of x and y and adjusting the composition ratio of In₁₋ₓGaₓAs_{y}P_{1-y}. The refractive index of InGaAsP has a characteristic of being lower than a refractive index of InP when the composition ratio thereof is close to a composition ratio of GaP, and being higher than the refractive index of InP when the composition ratio thereof is close to a composition ratio of InAs.

Using the above-described characteristic, a refractive index of active layer 11 can be made higher than a refractive index of each of first clad layer 6 and second clad layer 12. A material (composition ratio) constituting each of first clad layer 6 and second clad layer 12 can be selected from a material (composition ratio) that is lower in refractive index than a material constituting active layer 11. First clad layer 6 is made of, for example, p-type InP. Second clad layer 12 is made of, for example, n-type InP. The material constituting active layer 11 may be a quaternary mixed crystal other than InGaAsP and may be, for example, AlInGaAs or the like. Even with this, the refractive index of each of active layer 11, first clad layer 6 and second clad layer 12 can be set as described above by adjusting a composition ratio of the quaternary mixed crystal as appropriate. When the material constituting active layer 11 is AlInGaAs, first clad layer 6 may be p-type AlAs and second clad layer 12 may be n-type AlAs.

Active layer 11 of semiconductor laser portion 1 has a first end face 11A located opposite to transition portion 2 in the Y direction. First end face 11A is a cleaved surface. First end face 11A is covered with a not-shown reflective film (high reflection (HR) coating film). A reflectance of the reflective film is, for example, approximately 95%.

Diffraction grating layer 7 is embedded in first clad layer 6. Diffraction grating layer 7 is arranged closer to active layer 11 than semiconductor substrate 5 in the Z direction. Diffraction grating layer 7 has a plurality of portions that are spaced apart from each other in the X direction and arranged periodically. First clad layer 6 is arranged between the above-described plurality of portions of diffraction grating layer 7. Diffraction grating layer 7 and first clad layer 6 form a diffraction grating 10. A refractive index of diffraction grating layer 7 is higher than the refractive index of first clad layer 6. An average refractive index of diffraction grating 10 is higher than the refractive index of first clad layer 6 and lower than the refractive index of active layer 11. Diffraction grating layer 7 is made of, for example, p-type InGaAsP.

As shown in FIG. 4, fourth clad layer 15 is provided on a part of second clad layer 12 in the X direction. Fourth clad layer 15 is provided to overlap with diffraction grating 10 in the Z direction. In a cross section along the X direction and the Z direction (hereinafter, called “XY cross section”), fourth clad layer 15 is provided such that a width thereof in the X direction becomes gradually narrower toward second clad layer 12 in the Z direction. In other words, in the XZ cross section, fourth clad layer 15 has an inverted mesa shape with respect to second clad layer 12. In the above-described XZ cross section, fourth clad layer 15 has a side surface connected to an upper surface of second clad layer 12 and extending above the upper surface of second clad layer 12. An angle formed by the side surface of fourth clad layer 15 and the upper surface of second clad layer 12 with respect to the outside of fourth clad layer 15 is an acute angle. The width of fourth clad layer 15 in the X direction is, for example, constant in the Y direction. A refractive index of fourth clad layer 15 is lower than the refractive index of active layer 11. Fourth clad layer 15 is made of, for example, n-type InP.

Insulating layer 16 is provided to fill in the surroundings of fourth clad layer 15. Insulating layer 16 has a lower surface that is in direct contact with the side surface of fourth clad layer 15, an upper surface that is continuous to be flush with an upper surface of fourth clad layer 15 of semiconductor laser portion 1, and a pair of inner side surfaces that face each other in the X direction. Each of the pair of inner side surfaces is in direct contact with the above-described side surface of fourth clad layer 15. An interior angle formed by each of the pair of inner side surfaces of insulating layer 16 and the lower surface of insulating layer 16 is an acute angle. In the XZ cross section, insulating layer 16 has a mesa shape. From the perspective of suppressing entry of heat and water from the outside to the inside of semiconductor laser element 100, insulating layer 16 is preferably made of a material having relatively low hygroscopicity while having relatively high heat resistance. Insulating layer 16 is made of, for example, benzocyclobutene (hereinafter, referred to as “BCB”). Insulating layer 16 is made of, for example, photosensitive BCB.

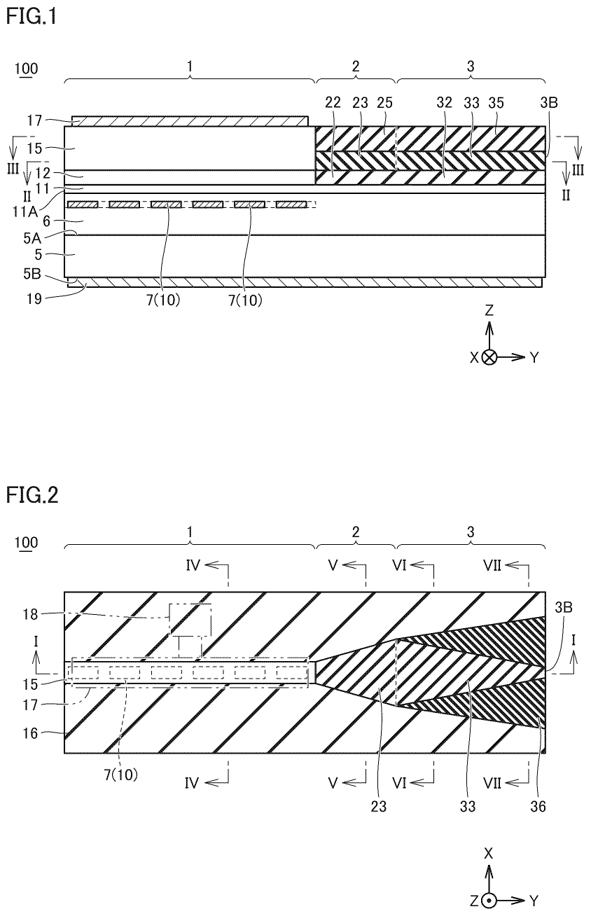

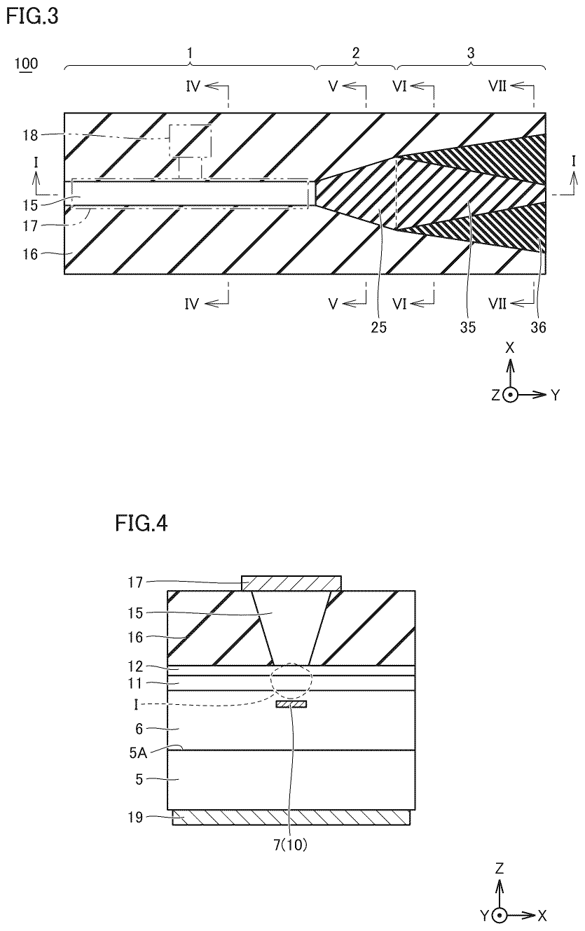

As shown in FIGS. 2 and 3, in a YZ cross section, each of semiconductor substrate 5, first clad layer 6, diffraction grating layer 7, active layer 11, second clad layer 12, fourth clad layer 15, and insulating layer 16 has a shape that is symmetric with respect to a center line of semiconductor laser portion 1 passing through the center in the X direction and extending along the Y direction. As shown in FIG. 4, in the XZ cross section, each of semiconductor substrate 5, first clad layer 6, diffraction grating layer 7, active layer 11, second clad layer 12, fourth clad layer 15, and insulating layer 16 has a shape that is symmetric with respect to a center line of semiconductor laser portion 1 passing through the center in the X direction and extending along the Z direction.

First electrode 17 is provided on fourth clad 15 layer and is electrically connected to fourth clad layer 15. Electrode pad 18 is provided on insulating layer 16 and is electrically connected to first electrode 17. Second electrode 19 is provided on second surface 5B of semiconductor substrate 5 and is electrically connected to semiconductor substrate 5.

### Configuration of Transition Portion 2

As shown in FIGS. 1 to 3 and 5, transition portion 2 includes semiconductor substrate 5, first clad layer 6, active layer 11, a second clad layer 22, a waveguide layer 23, a third clad layer 25, and insulating layer 16. Each of semiconductor substrate 5, first clad layer 6, active layer 11, and insulating layer 16 of transition portion 2 has a structure equivalent to that of each of semiconductor substrate 5, first clad layer 6, active layer 11, and insulating layer 16 of semiconductor laser portion 1. Each of semiconductor substrate 5, first clad layer 6, active layer 11, and insulating layer 16 of transition portion 2 is, for example, provided as the same component as each of semiconductor substrate 5, first clad layer 6, active layer 11, and insulating layer 16 of semiconductor laser portion 1. In other words, each of semiconductor substrate 5, first clad layer 6, active layer 11, and insulating layer 16 of transition portion 2 is formed simultaneously with each of semiconductor substrate 5, first clad layer 6, active layer 11, and insulating layer 16 of semiconductor laser portion 1 in a method for manufacturing semiconductor laser element 100. A configuration of transition portion 2 different from that of semiconductor laser portion 1 will be mainly described below.

First clad layer 6, active layer 11, second clad layer 22, waveguide layer 23, and third clad layer 25 are provided on first surface 5A and stacked in this order from the first surface 5A side in the Z direction. First clad layer 6 and second clad layer 22 are provided to sandwich active layer 11 in the Z direction. Each of first clad layer 6 and second clad layer 22 is in contact with active layer 11. Second clad layer 22 and third clad layer 25 are provided to sandwich waveguide layer 23 in the Z direction. Each of second clad layer 22 and third clad layer 25 is in contact with waveguide layer 23.

Waveguide layer 23 is provided on a part of second clad layer 22 to overlap with active layer 11 of transition portion 2 in the Z direction. Waveguide layer 23 has a lower surface that is in direct contact with a part of an upper surface of second clad layer 22 of transition portion 2, and an upper surface that is in direct contact with an entire lower surface of third clad layer 25. Waveguide layer 23 is sandwiched between insulating layers 16 in the X direction. Waveguide layer 23 further has a pair of side surfaces that are in contact with the pair of inner side surfaces of insulating layer 16 that face each other in the X direction.

As shown in FIG. 2, a width (thickness) of waveguide layer 23 in the Z direction is wider (thicker) than a width (thickness) of active layer 11 in the Z direction. As shown in FIGS. 2 and 5, a width of waveguide layer 23 in the X direction is narrower than a width of active layer 11 in the X direction. As shown in FIG. 2, in a cross section along the X direction and the Y direction (hereinafter, called “XY cross section”), waveguide layer 23 is provided such that the width thereof in the X direction becomes gradually wider with increasing distance from semiconductor laser portion 1 in the Y direction.

As shown in FIG. 5, in the XZ cross section, waveguide layer 23 is provided such that the width thereof in the X direction becomes gradually narrower toward second clad layer 22 in the Z direction. In other words, in the XZ cross section, waveguide layer 23 has an inverted mesa shape with respect to second clad layer 22. In the XZ cross section, an angle formed by the above-described side surface of waveguide layer 23 and the above-described upper surface of second clad layer 12 with respect to the outside of waveguide layer 23 is an acute angle. The width of active layer 11 of transition portion 2 in the X direction is equal to the width of active layer 11 of semiconductor laser portion 1 in the X direction.

A minimum width, in the X direction, of one end of waveguide layer 23 connected to semiconductor laser portion 1 in the Y direction is equal to a minimum width of fourth clad layer 15 in the X direction.

Third clad layer 25 is provided on waveguide layer 23. Third clad layer 25 has a lower surface that is in direct contact with the upper surface of waveguide layer 23, and an upper surface that is continuous to be flush with the upper surface of each of fourth clad layer 15 and the pair of insulating layers 16 of semiconductor laser portion 1. Third clad layer 25 is sandwiched between the pair of insulating layers 16 in the X direction. Third clad layer 25 further has a pair of side surfaces that are in contact with the pair of insulating layers 16.

As shown in FIGS. 3 and 5, a width of third clad layer 25 in the X direction is narrower than the width of active layer 11 in the X direction. As shown in FIG. 3, in the XY cross section, third clad layer 25 is provided such that the width thereof in the X direction becomes gradually wider with increasing distance from semiconductor laser portion 1 in the Y direction. As shown in FIG. 5, in the XZ surface, third clad layer 25 is provided such that the width thereof in the X direction becomes gradually narrower toward waveguide layer 23 in the Z direction. In other words, in the XZ cross section, waveguide layer 23 and third clad layer 25 have an inverted mesa shape with respect to second clad layer 22. In the XZ cross section, the above-described side surface of third clad layer 25 is, for example, continuous to be flush with the above-described side surface of waveguide layer 23.

A refractive index of second clad layer 22 is higher than the refractive index (effective refractive index) of active layer 11. A refractive index of waveguide layer 23 is higher than the refractive index of each of second clad layer 22 and third clad layer 25. The refractive index of third clad layer 25 is, for example, higher than the refractive index of fourth clad layer 15. Second clad layer 22 and waveguide layer 23 are transparent to light generated in active layer 11. “Transparent” herein means that a transmittance of the light generated in active layer 11 is equal to or higher than 90%.

Each of second clad layer 22, third clad layer 25 and waveguide layer 23 is obtained by adjusting the above-described composition ratio of the arbitrary quaternary mixed crystal as appropriate such that the refractive index of each of second clad layer 22, third clad layer 25 and waveguide layer 23 has the above-described relation. Waveguide layer 23 is, for example, i-type InGaAsP. Second clad layer 22 is, for example, n-type or i-type InGaAsP. Third clad layer 25 may be, for example, n-type or i-type InP. By adjusting the above-described composition ratio of each of active layer 11, second clad layer 22, third clad layer 25, and waveguide layer 23 as appropriate, the refractive index of second clad layer 22 becomes higher than the refractive index of active layer 11 and lower than the refractive index of waveguide layer 23. A material constituting second clad layer 22 and waveguide layer 23 may be a quaternary mixed crystal other than InGaAsP and may be, for example, AlInGaAs or the like.

As shown in FIGS. 2 and 3, in the YZ cross section, each component forming transition portion 2 has a shape that is symmetric with respect to a center line of transition portion 2 passing through the center in the X direction and extending along the Y direction. As shown in FIG. 5, in the XZ cross section, each component forming transition portion 2 has a shape that is symmetric with respect to a center line of transition portion 2 passing through the center in the X direction and extending along the Z direction.

### Configuration of SSC 3

SSC 3 includes semiconductor substrate 5, first clad layer 6, active layer 11, a second clad layer 32, a waveguide layer 33, a third clad layer 35, a pair of fifth clad layers 36, and the pair of insulating layers 16. Each of semiconductor substrate 5, first clad layer 6 and active layer 11 of SSC 3 has a structure equivalent to that of each of semiconductor substrate 5, first clad layer 6 and active layer 11 of semiconductor laser portion 1. Each of semiconductor substrate 5, first clad layer 6, active layer 11, and the pair of insulating layers 16 of SSC 3 is, for example, provided as the same component as each of semiconductor substrate 5, first clad layer 6, active layer 11, and the pair of insulating layers 16 of each of semiconductor laser portion 1 and transition portion 2. In other words, each of semiconductor substrate 5, first clad layer 6, active layer 11, and the pair of insulating layers 16 of SSC 3 is formed simultaneously with each of semiconductor substrate 5, first clad layer 6, active layer 11, and the pair of insulating layers 16 of each of semiconductor laser portion 1 and transition portion 2 in the method for manufacturing semiconductor laser element 100.

Furthermore, each of second clad layer 32, waveguide layer 33 and third clad layer 35 of SSC 3 has a structure equivalent to that of each of second clad layer 22, waveguide layer 23 and third clad layer 25 of transition portion 2. Each of second clad layer 32, waveguide layer 33 and third clad layer 35 of SSC 3 is, for example, provided as the same component as each of second clad layer 22, waveguide layer 23 and third clad layer 25 of transition portion 2. In other words, each of second clad layer 32, waveguide layer 33 and third clad layer 35 of SSC 3 is formed simultaneously with each of second clad layer 22, waveguide layer 23 and third clad layer 25 of transition portion 2 in the method for manufacturing semiconductor laser element 100. A configuration of SSC 3 different from those of semiconductor laser portion 1 and transition portion 2 will be mainly described below.

Each of second clad layer 32, waveguide layer 33, third clad layer 35, and fifth clad layer 36 of SSC 3 has a second end face 3B located opposite to transition portion 2 in the Y direction. Second end face 3B is a cleaved surface. Second end face 3B is an emission surface from which semiconductor laser element 100 emits a laser beam. Second end face 3B is covered with a not-shown antireflection (AR) film (AR coating film). Second end face 3B is coupled to an external optical system such as an optical fiber.

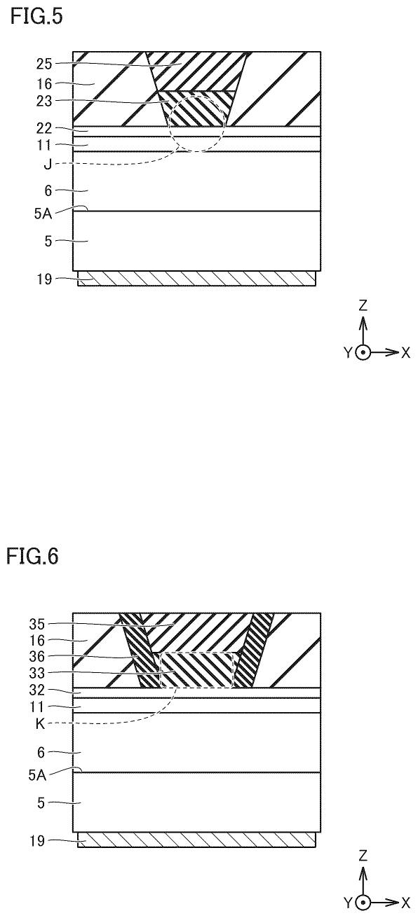

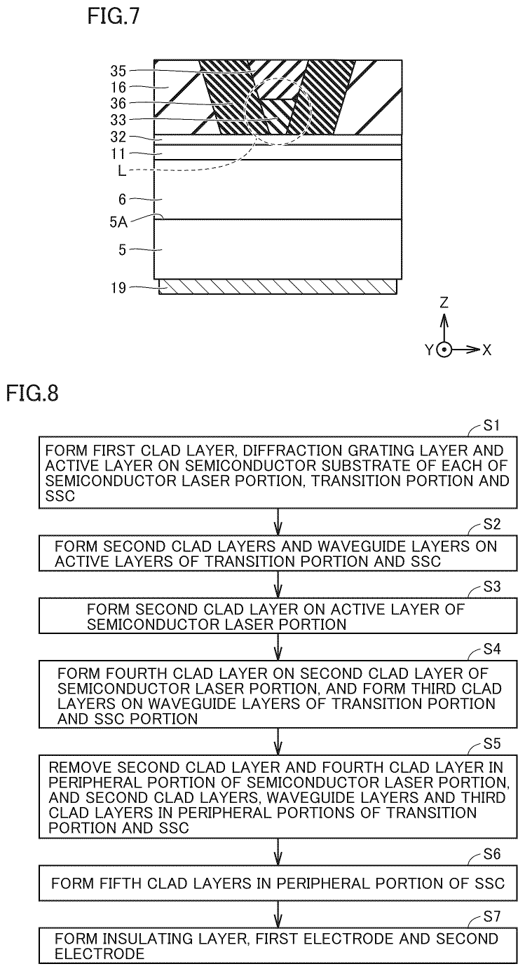

As described above, SSC 3 includes the pair of fifth clad layers 36. As shown in FIGS. 2, 3, 6, and 7, the pair of fifth clad layers 36 are provided to sandwich waveguide layer 33 in the X direction. As shown in FIGS. 6 and 7, each of the pair of fifth clad layers 36 is provided on second clad layer 32. In the XZ cross section, waveguide layer 33 is surrounded by second clad layer 32, third clad layer 35 and the pair of fifth clad layers 36. The pair of fifth clad layers 36 are, for example, provided to sandwich each of waveguide layer 33 and third clad layer 35 in the X direction.

As shown in FIGS. 2 and 3, in the YZ cross section, each of the pair of fifth clad layers 36 is provided such that a width thereof in the X direction becomes gradually wider with increasing distance from transition portion 2 in the Y direction. In the YZ cross section, each of the pair of fifth clad layers 36 has, for example, a triangular shape. In the YZ cross section, the widths of the pair of fifth clad layers 36 in the X direction are, for example, equal to each other.

As shown in FIG. 2, in the YZ cross section, waveguide layer 33 is provided such that a width thereof in the X direction becomes gradually narrower with increasing distance from transition portion 2 in the Y direction. In other words, in the YZ cross section, waveguide layer 33 is provided such that a width thereof in the X direction becomes gradually narrower toward second end face 3B in the Y direction. The width of waveguide layer 33 in the X direction is the narrowest in second end face 3B. A minimum width of waveguide layer 33 in the X direction is narrower than a minimum width of waveguide layer 23 in the X direction.

As shown in FIG. 3, in the YZ cross section, third clad layer 35 is provided such that a width thereof in the X direction becomes gradually narrower with increasing distance from transition portion 2 in the Y direction. A minimum width of third clad layer 35 in the X direction is narrower than a minimum width of third clad layer 25 in the X direction.

As shown in FIGS. 6 and 7, each of the pair of fifth clad layers 36 has a lower surface that is in contact with a part of an upper surface of second clad layer 32, an inner side surface that is in direct contact with a side surface of each of waveguide layer 33 and third clad layer 35, and an outer side surface that is in direct contact with the side surface of each of the pair of insulating layers 16, and an upper surface that is continuous to be flush with an upper surface of third clad layer 35 and each of the pair of insulating layers 16.

As shown in FIGS. 6 and 7, in the XZ cross section, a width of each of the pair of fifth clad layers 36 in the X direction is, for example, constant in the Z direction. In the XZ cross section, the widths of the pair of fifth clad layers 36 in the X direction are, for example, equal to each other.

A refractive index of second clad layer 32 is higher than the refractive index (effective refractive index) of active layer 11. A refractive index of waveguide layer 33 is higher than the refractive index of each of second clad layer 32 and third clad layer 35. A refractive index of fifth clad layer 36 is lower than the refractive index of waveguide layer 33.

Each of second clad layer 32, third clad layer 35, fifth clad layer 36, and waveguide layer 33 is obtained by adjusting the above-described composition ratio of the arbitrary quaternary mixed crystal such that the refractive index of each of second clad layer 32, third clad layer 35, fifth clad layer 36, and waveguide layer 33 has the above-described relation. Waveguide layer 33 is, for example, i-type InGaAsP. Second clad layer 32 may be, for example, n-type InGaAsP or i-type InGaAsP. Third clad layer 35 may be, for example, n-type InP or i-type InP. Fifth clad layer 36 may be, for example, i-type InP.

As shown in FIGS. 2 and 3, in the YZ cross section, each component forming SSC 3 has a shape that is symmetric with respect to a center line of SSC 3 passing through the center in the X direction and extending along the Y direction. As shown in FIGS. 6 and 7, in the XZ cross section, each component forming SSC 3 has a shape that is symmetric with respect to a center line of SSC 3 passing through the center in the X direction and extending along the Z direction.

### Method for Manufacturing Semiconductor Laser Element 100

Next, an example of the method for manufacturing semiconductor laser element 100 will be described. The method for manufacturing semiconductor laser element 100 includes, for example, the first step of forming, on first surface 5A of semiconductor substrate 5, an element region that is to become a plurality of semiconductor laser elements 100, and the second step of separating each of the plurality of semiconductor laser elements 100. As shown in, for example, FIG. 8, the first step includes the step of forming first clad layer 6, diffraction grating 10 and active layer 11 on first surface 5A of semiconductor substrate 5 (S1), the step of forming second clad layers 22 and 32 and waveguide layers 23 and 33 on active layers 11 of transition portion 2 and SSC 3 (S2), the step of forming second clad layer 12 on active layer 11 of semiconductor laser portion 1 (S3), the step of forming fourth clad layer 15 in semiconductor laser portion 1 and forming third clad layers 25 and 35 in transition portion 2 and SSC 3 (S4), the step of removing second clad layer 12 and fourth clad layer 15 in a peripheral portion other than a central portion of the semiconductor layer portion, and second clad layers 22 and 32, waveguide layers 23 and 33, and third clad layers 25 and 35 in peripheral portions other than central portions of transition portion 2 and SSC 3 (S5), the step of forming fifth clad layers 36 in the above-described peripheral portion of SSC 3 (S6), and the step of forming insulating layer 16, first electrode 17, second electrode 19 and the like (S7). In the first step, the step (S1) to the step (S7) are performed sequentially. The second step includes, for example, the step of forming a cleaved surface in each of second clad layer 32, waveguide layer 33, third clad layer 35, and fifth clad layer 36 to form second end face 3B.

In the step (S1), first clad layer 6 is formed on entire first surface 5A of semiconductor substrate 5, and then, diffraction grating 10 is formed only in a region where semiconductor laser portion 1 is to be formed, and then, active layer 11 is formed only in a region where active layer 11 is to be formed. A method for forming each component includes, for example, a vapor phase growth process, a photoengraving process and an etching process. As described above, although the material constituting the multiple quantum well layer and the barrier layers of active layer 11 may be arbitrarily selected depending on the emission wavelength, the material is, for example, a semiconductor material of a quaternary mixed crystal.

In the step (S2), second clad layers 22 and 32 and waveguide layers 23 and 33 are formed only in regions where transition portion 2 and SSC 3 are to be formed. A method for forming these clad layers and waveguide layers includes, for example, a vapor phase growth process, a photoengraving process and an etching process. As described above, the material (composition ratio) constituting each of second clad layers 22 and 32 and waveguide layers 23 and 33 is adjusted as appropriate such that the refractive index of each of second clad layers 22 and 32 is higher than the refractive index of active layer 11 and lower than the refractive index of each of waveguide layers 23 and 33.

In the step (S3), second clad layer 12 is formed only in the region where semiconductor laser portion 1 is to be formed. A method for forming these clad layers includes, for example, a vapor phase growth process, a photoengraving process and an etching process. As described above, the material (composition ratio) constituting second clad layer 12 is adjusted as appropriate such that the refractive index of second clad layer 12 is lower than the refractive index of active layer 11.

In the step (S4), fourth clad layer 15 is formed in the region where semiconductor laser portion 1 is to be formed, and third clad layers 25 and 35 are formed in the regions where transition portion 2 and SSC 3 are to be formed. A method for forming these clad layers includes, for example, a vapor phase growth process, a photoengraving process and an etching process. As described above, the material (composition ratio) constituting fourth clad layer 15 is adjusted as appropriate such that the refractive index of fourth clad layer 15 is lower than the refractive index of active layer 11. The material (composition ratio) constituting each of third clad layers 25 and 35 is adjusted as appropriate such that the refractive index of each of third clad layers 25 and 35 is lower than the refractive index of each of waveguide layers 23 and 33.

In the step (S5), second clad layer 12 and fourth clad layer 15 in the peripheral portion other than the central portion of semiconductor laser portion 1, and second clad layers 22 and 32, waveguide layers 23 and 33, and third clad layers 25 and 35 in the peripheral portions other than the central portions of transition portion 2 and SSC 3 are removed to form a mesa structure. A method for forming these clad layers includes a photoengraving process and an etching process.

In the step (S6), on second clad layer 32 of SSC 3, fifth clad layer 36 is formed on each of both sides of waveguide layer 33 and third clad layer 35 in the X direction. A method for forming this clad layer includes, for example, a vapor phase growth process, a photoengraving process and an etching process. As described above, the material (composition ratio) constituting fifth clad layer 36 is adjusted as appropriate such that the refractive index of fifth clad layer 36 is lower than the refractive index of waveguide layer 33.

In the step (S7), each of insulating layer 16, first electrode 17, electrode pad 18, and second electrode 19 is formed. A method for forming each of insulating layer 16, first electrode 17, electrode pad 18, and second electrode 19 includes, for example, a film formation process, a photoengraving process, a resin coating process, and an etching process.

### Operation of Semiconductor Laser Element 100

Next, the operation of semiconductor laser element 100 will be described. When a drive current flows between first electrode 17 and second electrode 19 and a carrier is injected into active layer 11 of semiconductor laser portion 1, inversion amplification occurs in active layer 11 and stimulated emission light is generated. Furthermore, the effect of diffraction grating 10 embedded under active layer 11 causes laser oscillation in which semiconductor laser portion 1 serves as a cavity. As a result, semiconductor laser element 100 functions as a distributed-feedback laser of an AR/HR coating.

Transition of a light propagation mode (waveguide) in semiconductor laser element 100 will be specifically described below with reference to FIGS. 4 to 7. Each of a region I in FIG. 4, a region J in FIG. 5, a region K in FIG. 6, and a region L in FIG. 7 shows a distribution, on the XZ cross section, of the light propagation mode on each XZ cross section. The light propagation mode is defined as a region where an intensity is equal to or larger than a predetermined value with respect to a maximum value thereof based on a light intensity distribution on each XZ cross section.

Region I in FIG. 4 shows the distribution of the light propagation mode on the XZ cross section in semiconductor laser portion 1. As shown by region I, in semiconductor laser portion 1, the light propagation mode on the XZ cross section has a distribution in the shape of a substantially small circle centered at active layer 11. Fourth clad layer 15 is connected to only a part of second clad layer 12. In other words, a connection region that connects fourth clad layer 15 and second clad layer 12 is narrower than a connection region that connects active layer 11 and second clad layer 12. A current injected from fourth clad layer 15 through second clad layer 12 into active layer 11 is limited to a current passing through the above-described connection region that connects fourth clad layer 15 and second clad layer 12. Therefore, a region of active layer 11 where inversion distribution occurs is also limited to a region directly under the above-described connection region. In addition, in semiconductor laser portion 1, the refractive index of active layer 11 is higher than the refractive index of each of first clad layer 6 and second clad layer 12 arranged around active layer 11. As a result of these, in semiconductor laser portion 1, the light propagation mode (waveguide) on the XZ cross section has the distribution in the shape of a substantially relatively small circle centered at active layer 11.

Furthermore, fourth clad layer 15 has an inverted mesa cross-sectional shape in the XZ cross section, and fourth clad layer 15 is connected to only a part of second clad layer 12 at the bottom of the inverted mesa shape. In this case, a width, in the X direction, of the connection region that connects fourth clad layer 15 and second clad layer 12 is narrower as compared with the case in which fourth clad layer 15 has a cross-sectional shape other than the inverted mesa shape, e.g., a forward mesa shape, in the XZ cross section. Therefore, a width, in the X direction, of the region where the current is injected from fourth clad layer 15 through second clad layer 12 into active layer 11 is also narrower, and the distribution of the light propagation mode on the XZ cross section is narrower.

The light generated in active layer 11 of semiconductor laser portion 1 is input to active layer 11 of transition portion 2. Region J in FIG. 5 shows the light propagation mode in transition portion 2. As shown by region J in FIG. 5, the light propagation mode in transition portion 2 is distributed between active layer 11 and waveguide layer 23. Second clad layer 22 and waveguide layer 23 of transition portion 2 are transparent to the light generated in active layer 11, and the refractive index of second clad layer 22 is higher than the refractive index of active layer 11 and the refractive index of waveguide layer 23 is higher than the refractive index of second clad layer 22. As a result, as shown by region J in FIG. 5, the light propagation mode makes gradual transition from active layer 11 to waveguide layer 23 in transition portion 2. The light propagation mode makes transition to waveguide layer 23 before reaching SSC 3.

Region K in FIG. 6 shows the light propagation mode formed on the transition portion 2 side relative to the center in the Y direction in SSC 3. Region L in FIG. 7 shows the light propagation mode formed on the second end face 3B side relative to the center in the Y direction in SSC 3. As shown by region K in FIG. 6, the light propagation mode on the transition portion 2 side in SSC 3 is distributed mainly in waveguide layer 33. On the other hand, as shown by region L in FIG. 7, the light propagation mode on the second end face 3B side in SSC 3 is distributed to leak and spread to second clad layer 32, third clad layer 35 and fifth clad layers 36 that are arranged to surround waveguide layer 33. This is because the width of waveguide layer 33 of SSC 3 in the X direction becomes gradually narrower toward second end face 3B of waveguide layer 33 in the Y direction. As a result, a spread angle of the light emitted from second end face 3B of SSC 3 can be suppressed, and thus, higher efficiency of coupling semiconductor laser element 100 to the external optical system is achieved. Therefore, the efficiency of coupling semiconductor laser element 100 to the external optical system is higher than that of a semiconductor laser element that does not include SSC 3.

### Effects of Semiconductor Laser Element 100

Next, the effects of semiconductor laser element 100 will be described based on the comparison with a comparative example. In a method for manufacturing a semiconductor laser element according to a comparative example in which an active layer of a laser portion of a semiconductor laser portion and a waveguide layer of an SSC are butt-connected in the Y direction, such as the semiconductor laser element described in PTL 1, it is necessary to remove the active layer formed in a region of the SSC, and then, grow a semiconductor layer, which is to become the waveguide layer, in the region and further process the semiconductor layer, to thereby form the waveguide layer that is butt-connected to the active layer.

In contrast, in semiconductor laser element 100, since each of transition portion 2 and SSC 3 includes waveguide layer 33, and waveguide layer 33 is in contact with a part of the upper surface of second clad layer 32 and has a refractive index higher than the refractive indexes of active layer 11 and second clad layer 32, the light propagation mode makes transition from active layer 11 to waveguide layer 23 in the Z direction in transition portion 2. Therefore, by growing semiconductor layers, which are to become waveguide layers 23 and 33, on active layer 11 and further processing the semiconductor layers without removing a part of active layer 11, waveguide layers 23 and 33 directly connected to active layer 11 can be formed. Thus, semiconductor laser element 100 allows lower manufacturing cost than that of the semiconductor laser element according to the above-described comparative example, although semiconductor laser element 100 includes SSC 3.

In semiconductor laser element 100, the refractive indexes of active layer 11, second clad layer 22 and waveguide layer 23 stacked in the Z direction in transition portion 2 are higher in the listed order. Therefore, in transition portion 2, the light propagation mode can make step-by-step transition in the order of active layer 11, second clad layer 22 and waveguide layer 23.

In semiconductor laser element 100, transition portion 2 and SSC 3 are provided on waveguide layers 23 and 33, respectively, and further include third clad layers 25 and 35 having the refractive indexes lower than those of waveguide layers 23 and 33. Third clad layers 25 and 35 limit spreading of the light propagation mode above waveguide layers 23 and 33 in transition portion 2 and SSC 3.

In semiconductor laser element 100, semiconductor laser portion 1 further includes fourth clad layer 15 provided on a part of second clad layer 12, and first electrode 17 provided on fourth clad layer 15 and electrically connected to fourth clad layer 15. Fourth clad layer 15 is provided such that the width thereof in the X direction becomes gradually narrower toward second clad layer 12 in the Z direction. In other words, in the XZ cross section, fourth clad layer 15 has an inverted mesa shape with respect to second clad layer 12. Therefore, in semiconductor laser element 100, the distribution of the light propagation mode of semiconductor laser portion 1 is smaller than that of a semiconductor layer element in which fourth clad layer 15 does not have an inverted mesa shape with respect to second clad layer 12, and thus, an operating current can be reduced.

In semiconductor laser element 100, the minimum value of the width of waveguide layer 23 of transition portion 2 in the X direction is equal to the minimum value of the width of fourth clad layer 15 of semiconductor laser portion 1 in the X direction. Furthermore, in transition portion 2, the width of waveguide layer 23 in the X direction becomes gradually narrower toward second clad layer 22 in the Z direction, and becomes gradually wider with increasing distance from semiconductor laser portion 1 in the Y direction. Therefore, the light entering transition portion 2 from semiconductor laser portion 1 is likely to make transition from active layer 11 to waveguide layer 23.

In semiconductor laser element 100, in SSC 3, the width of waveguide layer 33 in the X direction becomes gradually narrower with increasing distance from transition portion 2 in the Y direction. Therefore, the light propagation mode on the second end face 3B side of SSC 3 can be distributed to leak and spread to second clad layer 32, third clad layer 35 and fifth clad layers 36 that are arranged to surround waveguide layer 33.

In semiconductor laser element 100, the material constituting second clad layer 12 is InP, the material constituting second clad layers 22 and 32 is InGaAsP, and the material constituting waveguide layers 23 and 33 is InGaAsP. By appropriately setting the composition of InGaAsP of each layer, the refractive index of each of waveguide layers 23 and 33 can be made higher than the refractive index of each of second clad layers 12, 22 and 32.

### Second Embodiment

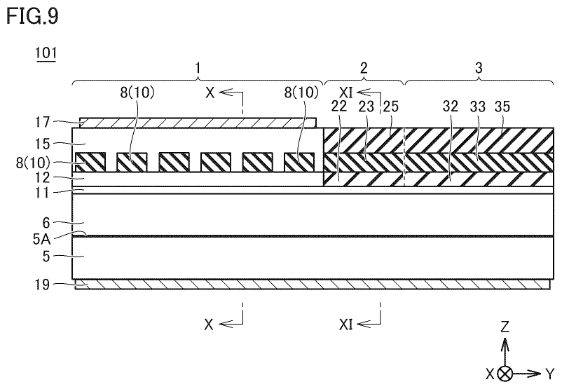

As shown in FIGS. 9 to 11, although a semiconductor laser element 101 according to a second embodiment is configured basically similarly to semiconductor laser element 100 according to the first embodiment, semiconductor laser element 101 is different from semiconductor laser element 100 in that semiconductor laser portion 1 includes a diffraction grating layer 8 embedded in fourth clad layer 15, instead of diffraction grating layer 7. The difference between semiconductor laser element 101 and semiconductor laser element 100 will be mainly described below.

Diffraction grating layer 8 is provided on second clad layer 12. Diffraction grating layer 8 has, for example, a lower surface that is in direct contact with the upper surface of second clad layer 12.

An average refractive index of diffraction grating 10 formed by diffraction grating layer 8 and fourth clad layer 15 is higher than the refractive index of fourth clad layer 15 and lower than the refractive index of active layer 11.

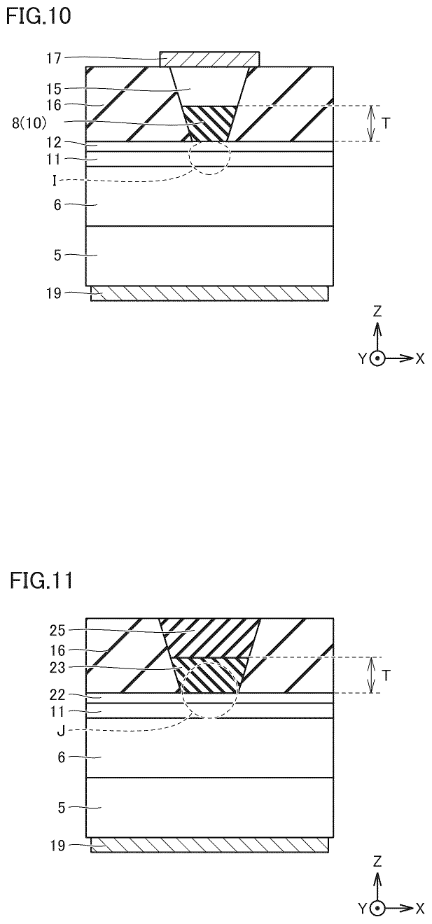

As shown in FIGS. 10 and 11, a width T (thickness) of diffraction grating layer 8 in the Z direction is equal to a width T (thickness) of waveguide layer 23 in the Z direction. A width of diffraction grating layer 8 in the X direction is narrower than the width of active layer 11 in the X direction. Diffraction grating layer 8 is provided such that the width thereof in the X direction becomes gradually narrower toward second clad layer 12 in the Z direction. A material constituting diffraction grating layer 8 is the same as the material constituting waveguide layer 23. A refractive index of diffraction grating layer 8 is higher than the refractive index of fourth clad layer 15. Diffraction grating layer 8 is made of, for example, InGaAsP.

Although a method for manufacturing semiconductor laser element 101 includes steps that are basically similar to those of the method for manufacturing semiconductor laser element 100, the method for manufacturing semiconductor laser element 101 is different from the method for manufacturing semiconductor laser element 100 in that diffraction grating layer 8 is formed in the same step as waveguide layers 23 and 33. The difference between the method for manufacturing semiconductor laser element 101 and the method for manufacturing semiconductor laser element 100 will be mainly described below.

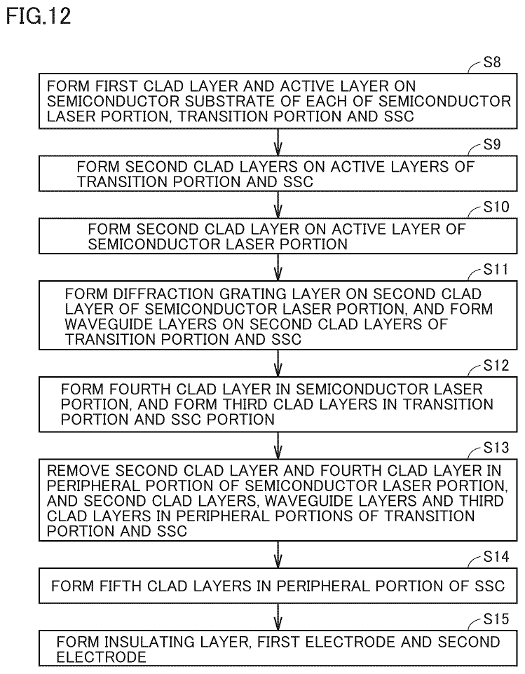

As shown in, for example, FIG. 12, a first step of the method for manufacturing semiconductor laser element 101 includes the step of forming first clad layer 6 and active layer 11 on first surface 5A of semiconductor substrate 5 (S8), the step of forming second clad layers 22 and 32 and waveguide layers 23 and 33 on active layers 11 of transition portion 2 and SSC 3 (S9), the step of forming second clad layer 12 on active layer 11 of semiconductor laser portion 1 (S10), the step of forming waveguide layers 23 and 33 and forming diffraction grating layer 8 (S11), the step of forming fourth clad layer 15 in semiconductor laser portion 1 and forming third clad layers 25 and 35 in transition portion 2 and SSC 3 (S12), the step of removing second clad layer 12 and fourth clad layer 15 in a peripheral portion other than a central portion of the semiconductor laser portion, and second clad layers 22 and 32, waveguide layers 23 and 33, and third clad layers 25 and 35 in peripheral portions other than central portions of transition portion 2 and SSC 3 (S13), the step of forming fifth clad layers 36 in the above-described peripheral portion of SSC 3 (S14), and the step of forming insulating layer 16, first electrode 17, second electrode 19 and the like (S15). In the first step, the step (S8) to the step (S15) are performed sequentially.

In the step (S8), first clad layer 6 is formed on entire first surface 5A of semiconductor substrate 5, and then, active layer 11 is formed only in a region where active layer 11 is to be formed. A method for forming each of first clad layer 6 and active layer 11 includes, for example, a vapor phase growth process, a photoengraving process and an etching process. As described above, although the material constituting active layer 11 may be arbitrarily selected depending on the emission wavelength, the material is, for example, a semiconductor material of a quaternary mixed crystal.

In the step (S9), second clad layers 22 and 32 are formed only in regions where transition portion 2 and SSC 3 are to be formed. A method for forming second clad layers 22 and 32 includes, for example, a vapor phase growth process, a photoengraving process and an etching process. As described above, the material (composition ratio) constituting each of second clad layers 22 and 32 is adjusted as appropriate such that the refractive index of each of second clad layers 22 and 32 is higher than the refractive index of active layer 11 and lower than the refractive index of each of waveguide layers 23 and 33.

In the step (S10), second clad layer 12 is formed only in a region where semiconductor laser portion 1 is to be formed. A method for forming these clad layers includes, for example, a vapor phase growth process, a photoengraving process and an etching process. As described above, the material (composition ratio) constituting second clad layer 12 is adjusted as appropriate such that the refractive index of second clad layer 12 is lower than the refractive index of active layer 11.

In the step (S11), formation of diffraction grating layer 8 in the region where semiconductor laser portion 1 is to be formed and formation of waveguide layers 23 and 33 in the regions where transition portion 2 and SSC 3 are to be formed are performed simultaneously. A method for forming these layers includes, for example, a vapor phase growth process, a photoengraving process and an etching process. The material (composition ratio) constituting each of diffraction grating layer 8 and waveguide layers 23 and 33 is adjusted as appropriate such that the refractive index of each of diffraction grating layer 8 and waveguide layers 23 and 33 is higher than the refractive index of each of second clad layers 22 and 32 and fourth clad layer 15.

In the step (S12), formation of fourth clad layer 15 in the region where semiconductor laser portion 1 is to be formed and formation of third clad layers 25 and 35 in the regions where transition portion 2 and SSC 3 are to be formed are performed simultaneously. A method for forming these clad layers includes, for example, a vapor phase growth process, a photoengraving process and an etching process. The material (composition ratio) constituting each of third clad layers 25 and 35 is adjusted as appropriate such that the refractive index of each of third clad layers 25 and 35 is lower than the refractive index of each of waveguide layers 23 and 33.

The steps (S13) to (S15) are performed similarly to the above-described steps (S5) to (S7), respectively. Semiconductor laser element 101 can thus be manufactured.

Semiconductor laser element 101 can operate similarly to semiconductor laser element 100. Although the refractive index of diffraction grating layer 8 is higher than the refractive index of fourth clad layer 15, the average refractive index of diffraction grating 10 formed by diffraction grating layer 8 and fourth clad layer 15 is lower than the refractive index of active layer 11. In addition, diffraction grating layer 8 is embedded in the bottom of fourth clad layer 15 having an inverted mesa shape. Therefore, a light propagation mode in semiconductor laser portion 1 does not spread to diffraction grating 10 and has a distribution that is substantially equivalent to that of semiconductor laser element 100.

Since transition portion 2 and SSC 3 of semiconductor laser element 101 are configured equivalently to those of semiconductor laser element 100, a light propagation mode in each of transition portion 2 and SSC 3 has a distribution that is substantially equivalent to that of semiconductor laser element 100.

Since diffraction grating layer 8 is formed in the same step as waveguide layers 23 and 33 in the method for manufacturing semiconductor laser element 101, the number of steps can be reduced as compared with the method for manufacturing semiconductor laser element 100. As a result, the manufacturing cost of semiconductor laser element 101 can be further reduced as compared with the manufacturing cost of semiconductor laser element 100.

### Modification

In each of semiconductor laser elements 100 and 101, the refractive index of each of second clad layers 22 and 32 may be equal to the refractive index of active layer 11, as long as the refractive index of each of second clad layers 22 and 32 is lower than the refractive index of each of waveguide layers 23 and 33.

### Third Embodiment

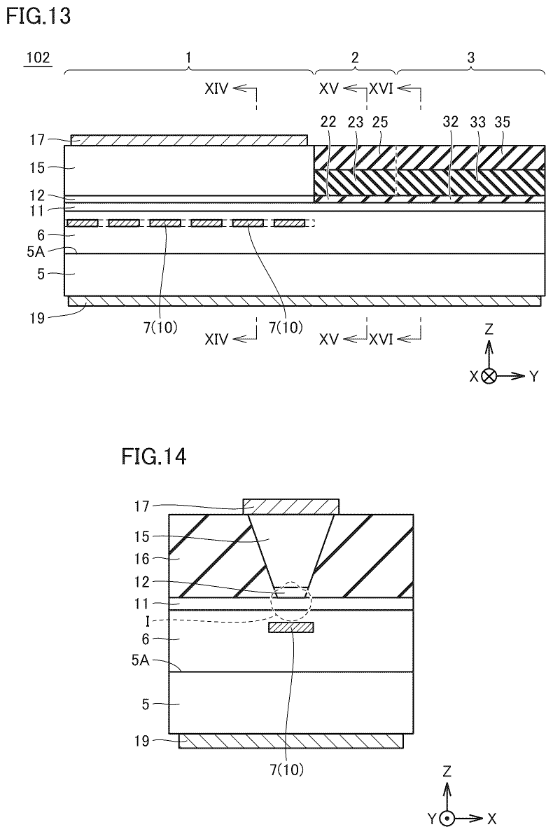

As shown in FIGS. 13 to 15, although a semiconductor layer element 102 according to a third embodiment is configured basically similarly to semiconductor laser element 100 according to the first embodiment, semiconductor layer element 102 is different from semiconductor laser element 100 in that second clad layer 12 in semiconductor laser portion 1 and second clad layers 22 and 32 in transition portion 2 and SSC 3 are arranged in a lowermost portion of an inverted mesa structure that is narrower than active layer 11, and the refractive index of second clad layer 12 in semiconductor laser portion 1 is higher than an average refractive index of active layer 11. The differences between semiconductor layer element 102 and semiconductor laser element 100 will be mainly described below.

As shown in FIG. 14, fourth clad layer 15 and second clad layer 12 are provided on a part of active layer 11 in the X direction. Fourth clad layer 15 is provided to overlap with the whole of second clad layer 12 in the Z direction. Fourth clad layer 15 and second clad layer 12 are provided to overlap with diffraction grating 10 in the Z direction. In a cross section along the X direction and the Z direction (hereinafter, called “XZ cross section”), fourth clad layer 15 and second clad layer 12 are provided such that widths thereof in the X direction become gradually narrower toward active layer 11 in the Z direction. In other words, in the XZ cross section, fourth clad layer 15 and second clad layer 12 have an inverted mesa shape. Fourth clad layer 15 is made of, for example, n-type InP.

The refractive index of second clad layer 12 is higher than the average refractive index of active layer 11. Preferably, a ratio of the refractive index of second clad layer 12 to the average refractive index of active layer 11 is higher than 100% and equal to or lower than 103%. The refractive index of second clad layer 12 is, for example, equal to the refractive index of each of second clad layers 22 and 32. The material constituting second clad layer 12 is, for example, the same as the material constituting each of second clad layers 22 and 32. Second clad layer 12 is made of, for example, n-type InGaAsP.

A region I in FIG. 14 shows a distribution of a light propagation mode in semiconductor laser portion 1 on the XZ cross section. As shown by region I, in semiconductor laser portion 1, the light propagation mode on the XZ cross section has a distribution in the shape of a substantially small circle centered at active layer 11. Second clad layer 12 is connected to only a part of active layer 11. That is, in the XZ cross section, the width of second clad layer 12 in the X direction is narrower than that of active layer 11. Therefore, in semiconductor layer element 102, although the refractive index of active layer 11 is slightly lower than the refractive index of second clad layer 12 that is in contact with this active layer 11 as described above, most of the light propagation mode (waveguide) can have the distribution in the shape of a substantially relatively small circle centered at active layer 11, without greatly decreasing the efficiency of coupling active layer 11 to second clad layer 12, similarly to semiconductor laser element 100.

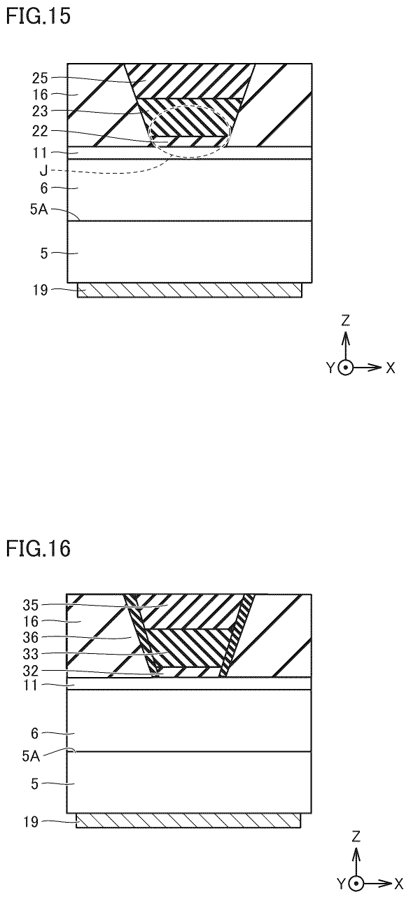

As shown in FIG. 15, in the XZ cross section of transition portion 2, second clad layer 22 is provided such that the width thereof in the X direction becomes gradually narrower toward active layer 11 in the Z direction. In other words, in the XZ cross section, third clad layer 25, waveguide layer 23 and second clad layer 22 have an inverted mesa shape.

As shown in FIG. 16, in the XZ cross section of SSC 3, second clad layer 32 is provided such that the width thereof in the X direction becomes gradually narrower toward active layer 11 in the Z direction. In other words, in the XZ cross section, third clad layer 35, waveguide layer 33 and second clad layer 32 have an inverted mesa shape.

Although a method for manufacturing semiconductor layer element 102 includes steps that are basically similar to those of the method for manufacturing semiconductor laser element 100, the method for manufacturing semiconductor layer element 102 is different from the method for manufacturing semiconductor laser element 100 in that second clad layer 12 of semiconductor laser portion 1 is formed in the same step as second clad layers 22 and 32 of transition portion 2 and SSC 3. The difference between the method for manufacturing semiconductor layer element 102 and the method for manufacturing semiconductor laser element 100 will be mainly described below.

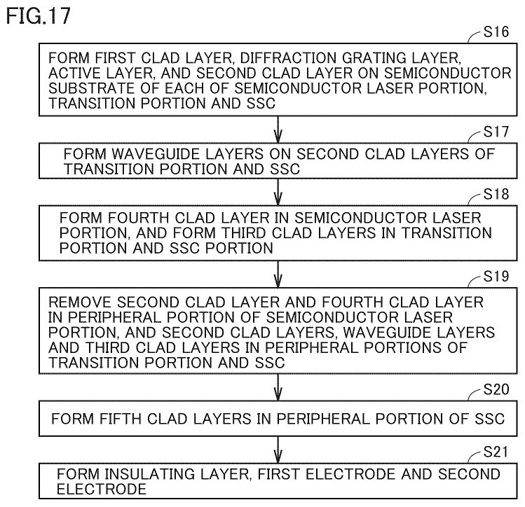

As shown in, for example, FIG. 17, a first step of the method for manufacturing semiconductor laser element 101 includes the step of forming first clad layer 6, diffraction grating layer 7, active layer 11, and second clad layers 12, 22 and 32 on first surface 5A of semiconductor substrate 5 (S16), the step of forming waveguide layers 23 and 33 on active layers 11 of transition portion 2 and SSC 3 (S17), the step of forming fourth clad layer 15 in semiconductor laser portion 1 and forming third clad layers 25 and 35 in transition portion 2 and SSC 3 (S18), the step of removing second clad layer 12 and fourth clad layer 15 in a peripheral portion other than a central portion of semiconductor laser portion 1, and second clad layers 22 and 32, waveguide layers 23 and 33, and third clad layers 25 and 35 in peripheral portions other than central portions of transition portion 2 and SSC 3 (S19), the step of forming fifth clad layers 36 in the above-described peripheral portion of SSC 3 (S20), and the step of forming insulating layer 16, first electrode 17 and second electrode 19 (S21). In the first step, the step (S16) to the step (S21) are performed sequentially.

In the step (S16), first clad layer 6 is formed on entire first surface 5A of semiconductor substrate 5. Next, active layer 11 is formed only in a region where active layer 11 is to be formed. Next, second clad layers 12, 22 and 32 are formed in regions where second clad layers 12, 22 and 32 are to be formed. A method for forming each layer includes, for example, a vapor phase growth process, a photoengraving process and an etching process. As described above, although the material constituting active layer 11 may be arbitrarily selected depending on the emission wavelength, the material is, for example, a semiconductor material of a quaternary mixed crystal. The material (composition ratio) constituting each of second clad layers 12, 22 and 32 is adjusted as appropriate such that the refractive index of each of second clad layers 12, 22 and 32 is higher than the refractive index of active layer 11 and lower than the refractive index of each of waveguide layers 23 and 33.

In the step (S17), waveguide layers 23 and 33 are formed only in regions where transition portion 2 and SSC 3 are to be formed. A method for forming these waveguide layers includes, for example, a vapor phase growth process, a photoengraving process and an etching process. As described above, the material (composition ratio) constituting each of waveguide layers 23 and 33 is adjusted as appropriate such that the refractive index of each of waveguide layers 23 and 33 is higher than the refractive index of each of second clad layers 22 and 32.

In the step (S18), fourth clad layer 15 is formed in a region where semiconductor laser portion 1 is to be formed, and third clad layers 25 and 35 are formed in the regions where transition portion 2 and SSC 3 are to be formed. A method for forming these clad layers includes, for example, a vapor phase growth process, a photoengraving process and an etching process. As described above, the material (composition ratio) constituting fourth clad layer 15 is adjusted as appropriate such that the refractive index of fourth clad layer 15 is lower than the refractive index of active layer 11. The material (composition ratio) constituting each of third clad layers 25 and 35 is adjusted as appropriate such that the refractive index of each of third clad layers 25 and 35 is lower than the refractive index of each of waveguide layers 23 and 33.

The steps (S19) to (S21) are performed similarly to the above-described steps (S5) to (S7), respectively. Semiconductor laser element 102 can thus be manufactured.

Although the embodiments of the present disclosure have been described above, the embodiments above can also be modified in various ways. In addition, the scope of the present disclosure is not limited to the embodiments above. The scope of the present disclosure is defined by the terms of the claims and is intended to include any modifications within the scope and meaning equivalent to the terms of the claims.

### REFERENCE SIGNS LIST

1 semiconductor laser portion; 2 transition portion; 3B second end face; 5 semiconductor substrate; 5A first surface; 5B second surface; 6 first clad layer; 7, 8 diffraction grating layer; 10 diffraction grating; 11 active layer; 11A first end face; 12, 22, 32 second clad layer; 15 fourth clad layer; 16 insulating layer; 17 first electrode; 18 electrode pad; 19 second electrode; 23, 33 waveguide layer; 25, 35 third clad layer; 36 fifth clad layer; 100, 101, 102 semiconductor laser element.

1. A semiconductor laser element comprising:
a semiconductor laser portion;
a transition portion that is adjacent to the semiconductor laser portion in a first direction and receives light emitted from the semiconductor laser portion; and
a spot size converter that is adjacent to the transition portion in the first direction and receives the light emitted from the transition portion, wherein
each of the semiconductor laser portion, the transition portion and the spot size converter includes:
a semiconductor substrate having a first surface extending along the first direction and a second direction orthogonal to the first direction; and
a first clad layer, an active layer and a second clad layer stacked on the first surface in this order from the first surface side in a third direction orthogonal to the first surface,
the active layer of each of the transition portion and the spot size converter is provided as the same component as the active layer of semiconductor laser portion.
the second clad layer is in contact with the active layer,
in the transition portion and the spot size converter, a refractive index of the second clad layer is higher than a refractive index of the active layer, and
each of the transition portion and the spot size converter further includes a waveguide layer that is in contact with a part of an upper surface of the second clad layer and has a refractive index higher than the refractive indexes of the active layer and the second clad layer.

2. The semiconductor laser element according to claim 1, wherein in the semiconductor laser portion, the refractive index of the second clad layer is lower than the refractive index of the active layer.

3. The semiconductor laser element according to claim 2, wherein
the semiconductor laser portion further includes:
a fourth clad layer provided on a part of the second clad layer; and
an electrode provided on the fourth clad layer and electrically connected to the fourth clad layer, and
the fourth clad layer is provided such that a width thereof in the second direction becomes gradually narrower toward the second clad layer in the third direction.

4. The semiconductor laser element according to claim 3, wherein
the semiconductor laser portion further includes a diffraction grating layer embedded in the fourth clad layer, and
an average refractive index of a diffraction grating formed by the diffraction grating layer and the fourth clad layer is higher than a refractive index of the fourth clad layer and lower than the refractive index of the active layer.

5. The semiconductor laser element according to claim 4, wherein
a material constituting the diffraction grating layer is the same as a material constituting the waveguide layer, and
a thickness of the diffraction grating layer in the third direction is equal to a thickness of the waveguide layer in the third direction.

6. The semiconductor laser element according to claim 1, wherein
in the semiconductor laser portion, the second clad layer is provided on a part of the active layer,
the semiconductor laser portion further includes:
a fourth clad layer provided on the second clad layer; and
an electrode provided on the fourth clad layer and electrically connected to the fourth clad layer,
the fourth clad layer and the second clad layer are provided such that widths thereof in the second direction become gradually narrower toward the active layer in the third direction, and
in the semiconductor laser portion, the refractive index of the second clad layer is higher than the refractive index of the active layer.

7. The semiconductor laser element according to claim 3, wherein
in the transition portion, a width of the waveguide layer in the second direction is narrower than a width of the active layer in the second direction,
in each of the transition portion and the spot size converter, the width of the waveguide layer in the second direction becomes gradually narrower toward the second clad layer in the third direction, and the width of the waveguide layer in the second direction becomes gradually wider with increasing distance from the semiconductor laser portion in the first direction, and
a minimum value of the width of the waveguide layer in the second direction in the transition portion is equal to a minimum value of the width of the fourth clad layer in the second direction in the semiconductor laser portion.

8. The semiconductor laser element according to claim 1, wherein
a material constituting the waveguide layer is InGaAsP.

9. The semiconductor laser element according to claim 1, wherein
a material constituting the waveguide layer is AlInGaAs.

10. The semiconductor laser element according to claim 4, wherein
in the transition portion, a width of the waveguide layer in the second direction is narrower than a width of the active layer in the second direction,
in each of the transition portion and the spot size converter, the width of the waveguide layer in the second direction becomes gradually narrower toward the second clad layer in the third direction, and the width of the waveguide layer in the second direction becomes gradually wider with increasing distance from the semiconductor laser portion in the first direction, and
a minimum value of the width of the waveguide layer in the second direction in the transition portion is equal to a minimum value of the width of the fourth clad layer in the second direction in the semiconductor laser portion.

11. The semiconductor laser element according to claim 5, wherein
in the transition portion, a width of the waveguide layer in the second direction is narrower than a width of the active layer in the second direction,
in each of the transition portion and the spot size converter, the width of the waveguide layer in the second direction becomes gradually narrower toward the second clad layer in the third direction, and the width of the waveguide layer in the second direction becomes gradually wider with increasing distance from the semiconductor laser portion in the first direction, and
a minimum value of the width of the waveguide layer in the second direction in the transition portion is equal to a minimum value of the width of the fourth clad layer in the second direction in the semiconductor laser portion.

12. The semiconductor laser element according to claim 6, wherein
in the transition portion, a width of the waveguide layer in the second direction is narrower than a width of the active layer in the second direction,
in each of the transition portion and the spot size converter, the width of the waveguide layer in the second direction becomes gradually narrower toward the second clad layer in the third direction, and the width of the waveguide layer in the second direction becomes gradually wider with increasing distance from the semiconductor laser portion in the first direction, and
a minimum value of the width of the waveguide layer in the second direction in the transition portion is equal to a minimum value of the width of the fourth clad layer in the second direction in the semiconductor laser portion.

13. The semiconductor laser element according to a claim 2, wherein
a material constituting the waveguide layer is InGaAsP.

14. The semiconductor laser element according to a claim 3, wherein
a material constituting the waveguide layer is InGaAsP.

15. The semiconductor laser element according to a claim 4, wherein
a material constituting the waveguide layer is InGaAsP.

16. The semiconductor laser element according to a claim 5, wherein
a material constituting the waveguide layer is InGaAsP.

17. The semiconductor laser element according to a claim 2, wherein
a material constituting the waveguide layer is AlInGaAs.

18. The semiconductor laser element according to a claim 3, wherein
a material constituting the waveguide layer is AlInGaAs.

19. The semiconductor laser element according to claim 4, wherein
a material constituting the waveguide layer is AlInGaAs.

20. The semiconductor laser element according to claim 5, wherein
a material constituting the waveguide layer is AlInGaAs.
